(19) United States
(12) Patent Application Publication
(10) Pub. No.: US 2011/0157451 A1
(43) Pub. Date: Jun. 30, 2011

(54) IMAGING DEVICE

(75) Inventor: JEN-TSORNG CHANG, Tu-Cheng (TW)

(73) Assignee: HON HAI PRECISION INDUSTRY CO., LTD., Tu-Cheng (TW)

(21) Appl. No.: 12/820,028

(22) Filed: Jun. 21, 2010

(30) Foreign Application Priority Data
Dec. 31, 2009 (CN) 200910312768.1

(51) Int. Cl. H04N 11/06

(52) U.S. Cl. 348/336; 348/E11.007

(57) ABSTRACT

An exemplary imaging device includes first camera modules, second camera modules, third camera modules, and a processing device. The first camera modules each have a red filter and is capable of capturing red images. The second camera modules each have a green filter and is capable of capturing green images. The third camera module each have a blue filter and is capable of capturing blue images. The processing device is electronically connected with the first, second, and third camera modules to combine the red, green, and blue images to form a full-color image. The imaging device can also include one or more fourth camera module, which includes an IR-cut filter.

### BACKGROUND

1. Technical Field

The present disclosure relates to an imaging device with monochromatic camera modules.

2. Description of Related Art

A traditional camera module 1 shown in FIG. 8 includes a sensor 2, a filter 3, and a lens group 4. Visible light passes through the lens group 4 and the filter 3, and then strikes the sensor 2 to form a plurality of images. The visible light is a mixture of monochromatic light with multiple wavelengths from about 390 nm to 750 nm, and every monochromatic light has a wavelength range and a corresponding refractive index. The focal length and the field of view are therefore different from one monochromatic light to another. In order to minimize chromatic aberration due to these differences, combinations of convex and concave lenses as well as aspheric lenses are often used in the camera module 1. However, stacked multiple number of lenses increase the thickness of the lens group 4.

### BRIEF DESCRIPTION OF THE DRAWINGS

Many aspects of the present imaging device can be better understood with reference to the following drawings. The components in the drawings are not necessarily drawn to scale, the emphasis instead being placed upon clearly illustrating the principles of the present imaging device. Moreover, in the drawings, like reference numerals designate corresponding parts throughout the views.

FIG. 1 is a schematic view of an imaging device in accordance with a first exemplary embodiment, wherein a first camera module, a second camera module and a third camera module are shown.

FIG. 2 is a schematic view of the difference between the field angle of the imaging device and that of one camera module as selected from among the first camera module, the second camera module, and the third camera module shown in FIG. 1.

FIG. 3 is a schematic view of an image shifting distance between the imaging device and one of the three camera modules shown in FIG. 1.

FIG. 4 shows a pattern of the camera module assembly shown in FIG. 1.

FIG. 5 shows a pattern of the camera module assembly in accordance with a second exemplary embodiment.

FIG. 6 shows a pattern of the camera module assembly in accordance with a third exemplary embodiment.

FIG. 7 shows a pattern of the camera module assembly in accordance with a fourth exemplary embodiment.

FIG. 8 shows a camera module of prior art.

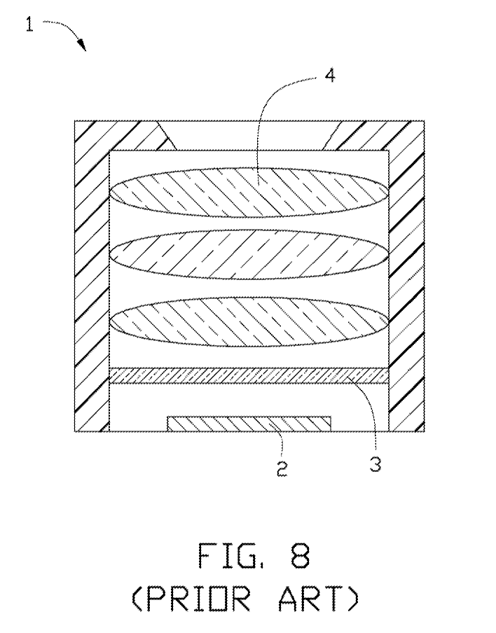

### DETAILED DESCRIPTION

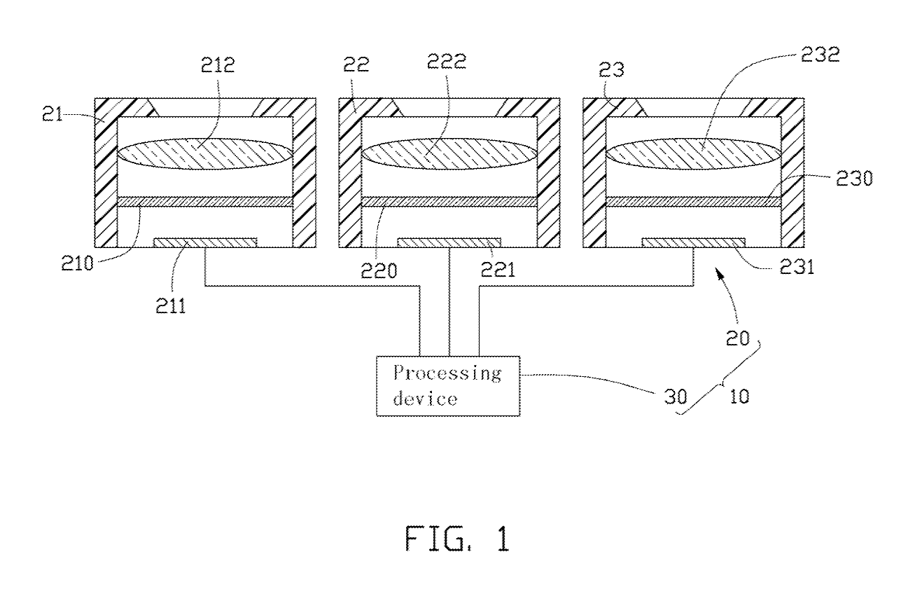

Referring to FIGS. 1 to 4, an imaging device 10, according to a first exemplary embodiment, includes a camera module assembly 20 and a processing device 30.

The camera module assembly 20 includes first camera modules 21, second camera modules 22, and third camera modules 23. The first camera module 21 includes a red filter 210, a lens 212, and a sensor 211 to capture a plurality of red images. The second camera module 22 includes a green filter 220, a lens 222, and a sensor 221 to capture a plurality of green images. The third camera module 23 includes a blue filter 230, a lens 232, and a sensor 231 to capture a plurality of blue images. That is, the first, second, and third camera modules 21, 22, and 23 each obtained or captured monochromatic images. The focusing range can be configured according to needs. The first camera module 21 has a focusing range from 60 cm to infinity. The second camera module 22 has a focusing range from 40 cm to 60 cm, and the third camera module 23 from 30 cm to 40 cm.

The processing device 30 is electrically connected with all of the camera modules 21, 22, and 23 to capture various monochromatic images to obtain a full-color image by interpolation methods.

Because every camera module uses a monochromatic filter, thereby permitting the corresponding monochromatic light to pass through, and the corresponding lens is designed according to the properties of the corresponding monochromatic light to eliminate aberration, fewer lenses, and in fact, only a single lens is needed in each camera module. The first, second, and third camera modules 21, 22, 23, and therefore the camera module assembly 20 can be thinner than the traditional camera module 1. In this embodiment, the height of the camera module assembly 20 is one third of that of the traditional camera module 1.

In this embodiment, the first, second, and third camera modules 21, 22, and 23 can be made using a plurality of 8 inch silicon wafers, and the size of the camera module is smaller; for example, each of the first, second, and third camera modules 21, 22, and 23 has a thickness of 3 mm to 11 mm, and the size of the sensor inside the wafer camera module is about 2 mm×2 mm.

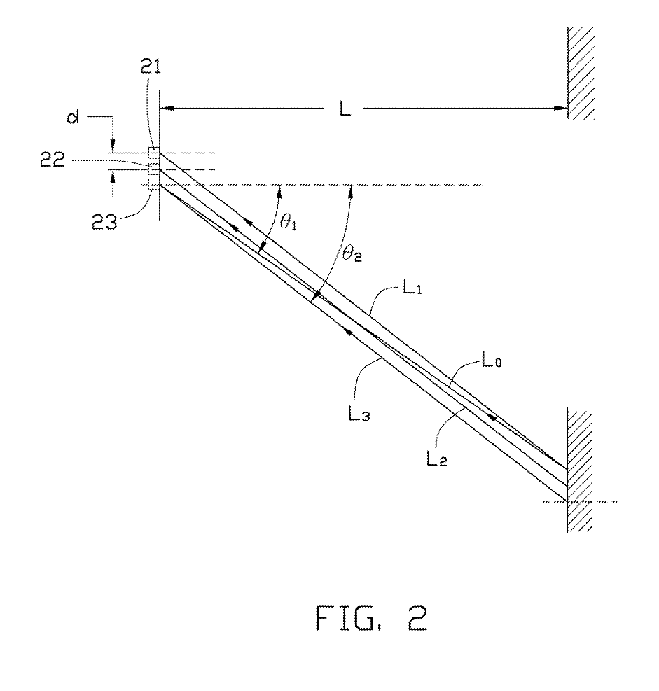

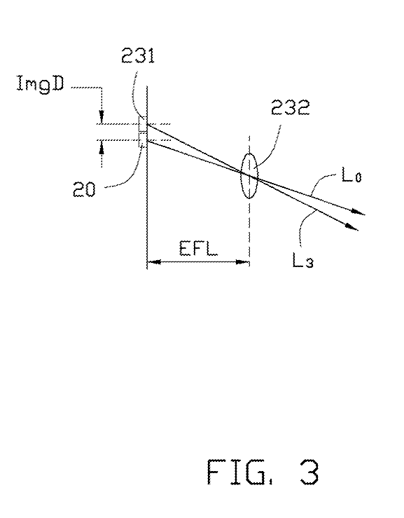

Further, the distance between any two neighboring camera modules is 4 mm or less. Referring to FIGS. 2 and 3, equations (1) to (2), and table 1, the relationship between the distance and the quality of the image will be shown.

Δθ=φ2−φ1˜d/L (1)

ImgD˜EFL×Δθ (2)

d is the distance between two neighboring camera modules, and L is the object distance. For each of the first, the second, and the third camera module 21, 22, and 23 is located differently in the camera module assembly 20, thus they each have different field angles according to the light entering the periphery of the lens thereof. L₁ is the light entering the periphery of the lens of the first camera module 21. L₂ is the light entering the periphery of the lens of the second camera module 22. L₃ is the light entering the periphery of the lens of the third camera module 23. L₀ is an imaginary light beam entering the periphery of an imaginary lens of the imaging device 10 while viewing the imaging device 10 as one camera module. θ₁ is the field angle of the imaging device 10. θ₂ is the field angle of one camera module, for example, the third camera module 23. Δθ is the difference between θ₁ and θ₂. EFL is the effective focal length. Im gD is an image shifting distance between one of the three camera modules 21, 22, 23 and the imaging device 10. The image shifting distance exists because each camera module is capable of capturing a monochromatic image, and the imaging device is also capable of obtaining a final image. The image shifting distance reflects the difference between the monochromatic image and the final image on distance. It is obvious that the smaller the image shifting difference is, the more the imaging device behave as one camera module. In this embodiment, EFL is the length between the imaging plane of the third camera module 23 and the optical center of the lens 231, and the imaging device 10 has the same EFL as the third camera module 23. We obtain Im gD using the equations (1) to (2), if EFL is 3 mm, and L is 300 mm.

TABLE 1

d

| | | |
|---|---|---|
| Im gD (mm) | 6 mm | 4 mm |

| | | | |
|---|---|---|---|
| L | 300 mm | 0.060 | 0.040 |
| | 400 mm | 0.045 | 0.030 |
| | 500 mm | 0.036 | 0.024 |
| | 600 mm | 0.030 | 0.020 |
| | 700 mm | 0.025 | 0.017 |

Table 1 shows that Im gD decreases with decreases in d while the object length L stays constant. The imaging device 10 has a longer focusing range than the traditional camera module 1, that is, the EFL is shorter than before.

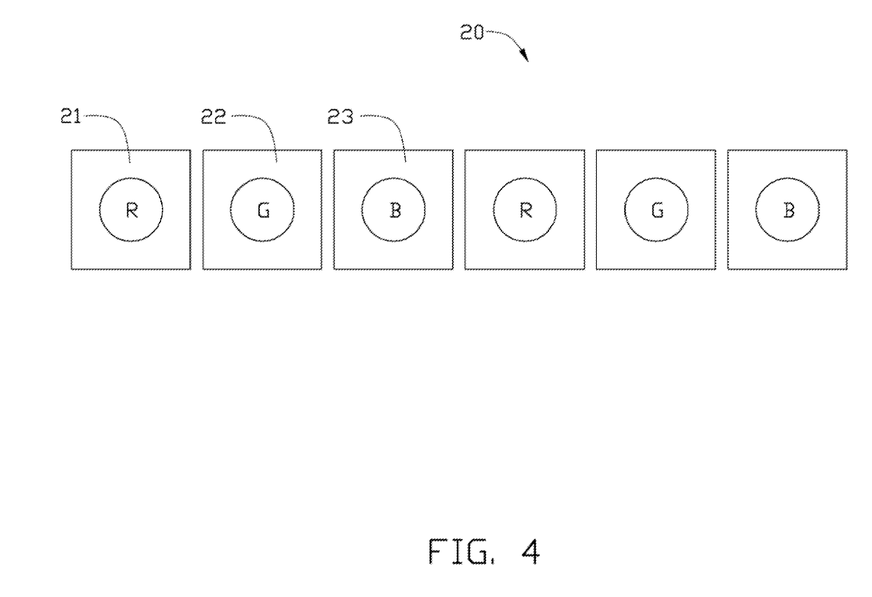

Referring to FIG. 4, R is the first camera module 21 with the red filter 210, G is the second camera module 22, and B is the third camera module 23. In the camera module assembly 20, the first, second, and third camera modules 21, 22, and 23 are arranged in a line.

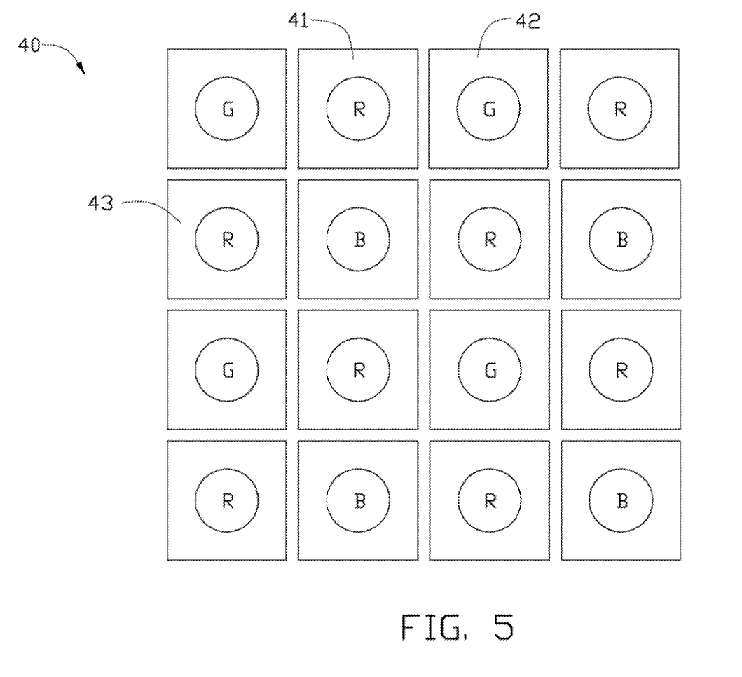

Referring to FIG. 5, a camera module assembly 40 of a second exemplary imaging device includes a first camera modules 41, a second camera modules 42, and a third camera modules 43, and which is aligned as bayer pattern.

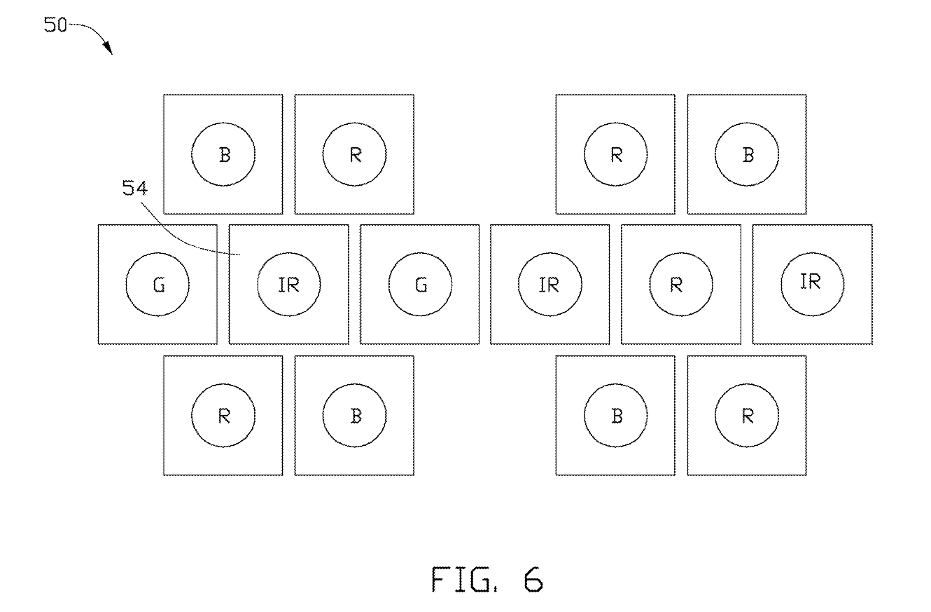

Referring to FIG. 6, a camera module assembly 50 of a third exemplary imaging device also includes at least a fourth camera module 54 labeled as IR. The fourth camera module 54 includes an IR-cut filter (not shown) and is configured to sense the intensity of the light entering the camera module 54. The intensity information is used to increase the brightness of the final image.

The first camera modules, the second camera modules, the third camera modules and a fourth camera module 54 are arranged in a repeating honeycomb pattern in the camera module assembly 50.

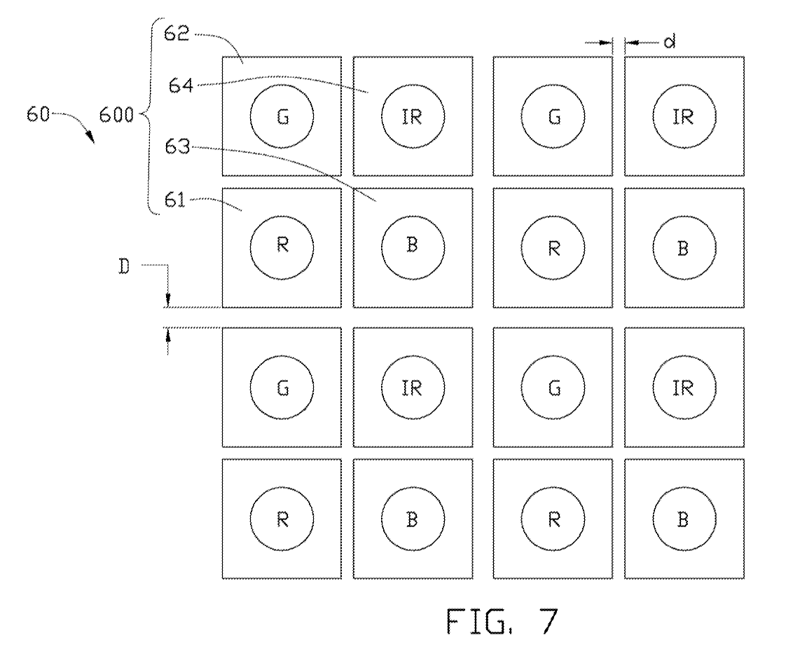

A camera module assembly 60 of a fourth exemplary embodiment is shown in FIG. 7. The camera module assembly 60 includes a plurality of units 600, and each of the units 600 includes a first, a second, a third, and a fourth camera module 61, 62, 63, and 64. Every two neighboring units 600 has a gap D, and every two neighboring camera modules in a unit has a gap d, and d is narrower than D.

It is understood that the above-described embodiments are intended to illustrate rather than limit the disclosure. Variations may be made to the embodiments without departing from the spirit of the disclosure. Accordingly, it is appropriate that the appended claims be construed broadly and in a manner consistent with the scope of the disclosure.

What is claimed is:

1. An imaging device, comprising:
a plurality of first camera modules, each of the first camera module having a red filter, capable of capturing a plurality of red images;
a plurality of second camera modules, each of the second camera module having a green filter, capable of capturing a plurality of green images;
a plurality of third camera modules, each of the third camera module having a blue filter, capable of capturing a plurality of blue images; and
a processing device, wherein the processing device is electronically connected with the first, second, and third camera modules to combine the red, green, and blue images to form a full-color image.

2. The image device as claimed in claim 1, wherein the first camera module, the second camera module, and the third camera module, each has a single lens therein.

3. The imaging device as claimed in claim 1, wherein the distance between every two neighboring camera modules in the first, second, and third camera modules is not greater than 4 mm.

4. The imaging device as claimed in claim 1, wherein the first, second, and third camera modules are arranged in one line.

5. The imaging device as claimed in claim 1, wherein the first, second, and third camera modules are arranged in a bayer pattern.

6. The imaging device as claimed in claim 1, wherein the first, second, and third camera modules are arranged in a repeating honeycomb pattern.

7. The imaging device as claimed in claim 1, further comprising:
at least one fourth camera module, electrically connected to the processing device, wherein the at least one fourth camera module includes an IR-cut filter.

8. The imaging device claimed in claim 7, wherein the pluralities of first, second, third camera modules, and the fourth camera module are arranged in a line.

9. The imaging device claimed in claim 7, wherein the pluralities of first, second, third camera modules, and the fourth camera module are arranged in a repeating honeycomb pattern.

10. The image device claimed in claim 7, wherein the first camera modules, the second camera modules, the third camera modules, and the fourth camera modules form at least two units, each unit comprising a first camera module, a second camera module, a third camera module, and a fourth camera module, the gap distance between every two neighboring units is greater than the gap distance of every two neighboring camera modules in a unit.
